(19) United States
(12) Patent Application Publication
(10) Pub. No.: US 2026/0066211 A1
(43) Pub. Date: Mar. 5, 2026

(54) ION SOURCE WITH COAXIAL GAS CONDUIT

(71) Applicant: Applied Materials, Inc., Santa Clara, CA (US)

(72) Inventors: Klaus Becker, Kensington, NH (US); Adam M. McLaughlin, Merrimac, MA (US); Graham Wright, Newburyport, MA (US)

(21) Appl. No.: 18/818,824

(22) Filed: Aug. 29, 2024

(51) Int. Cl. H01J 37/08; H01J 37/317

(52) U.S. Cl. CPC H01J 37/08; H01J 37/3171; H01J 2237/002

(57) ABSTRACT

An ion source includes a coaxial gas conduit is disclosed. The coaxial gas conduit includes two conduits, where the inner conduit defines an inner channel that delivers the gas that is subject to decomposition. The outer conduit and the inner conduit define an outer annular channel that delivers a gas that is less susceptible to decomposition, such as an inert or diluent gas. This coaxial gas conduit is configured such that only the outer conduit physically contacts the walls of the ion source. This serves to lower the temperature of the inner conduit and the gas flowing therethrough. Further, in some embodiments, the inner conduit may be in thermal contact with a heat sink to further lower its temperature.

### FIELD

Embodiments of the present disclosure relate to an ion source and more particularly, an ion source having a coaxial gas conduit.

### BACKGROUND

Various types of ion sources may be used to create the ions that are used in semiconductor processing equipment. For example, an indirectly heated cathode (IHC) ion source operates by supplying a current to a filament disposed behind a cathode. The filament emits thermionic electrons, which are accelerated toward and heat the cathode, in turn causing the cathode to emit electrons into the arc chamber of the ion source. The cathode is disposed at one end of an arc chamber. A repeller may be disposed on the end of the arc chamber opposite the cathode. The cathode and repeller may be biased so as to repel the electrons, directing them back toward the center of the arc chamber. In some embodiments, a magnetic field is used to further confine the electrons within the arc chamber. A plurality of sides is used to connect the two ends of the arc chamber.

An extraction aperture is disposed along one of these sides, proximate the center of the arc chamber, through which the ions created in the arc chamber may be extracted.

In certain embodiments, gasses are introduced into the ion source through a gas inlet. However, some of these gasses may be subject to decomposition. For example, the heat generated in the ion source may cause the gas to decompose, which causes the deposition of unwanted material in the ion source and in the gas conduit. In some embodiments, the decomposed material may ultimately clog the gas conduit.

To address this, frequent maintenance of the ion source may be performed. However, this solution is expensive, as it reduces the operating time of the ion source, lowering throughput.

Therefore, an ion source that is capable of introducing these gasses without decomposition would be beneficial.

### SUMMARY

An ion source that includes a coaxial gas conduit is disclosed. The coaxial gas conduit includes two conduits, where the inner conduit defines an inner channel that delivers the gas that is subject to decomposition. The outer conduit and the inner conduit define an outer annular channel that delivers a gas that is less susceptible to decomposition, such as an inert or diluent gas. This coaxial gas conduit is configured such that only the outer conduit physically contacts the walls of the ion source. This serves to lower the temperature of the inner conduit and the gas flowing therethrough. Further, in some embodiments, the inner conduit may be in thermal contact with a heat sink to further lower its temperature.

According to one embodiment, an indirectly heated cathode ion source is disclosed. The indirectly heated cathode ion source comprises an arc chamber, comprising a plurality of walls; an indirectly heated cathode disposed in the arc chamber; a coaxial gas conduit to introduce one or more feed gasses to the arc chamber, wherein the coaxial gas conduit comprises: an inner conduit defining an inner channel to introduce a first feed gas into the arc chamber; and an outer conduit. In some embodiments, the outer conduit is affixed to one wall of the plurality of walls of the arc chamber and the inner conduit is thermally isolated from the outer conduit at its distal end. In some embodiments, a distal end of the inner conduit extends toward the arc chamber as far as a distal end of the outer conduit. In some embodiments, a distal end of the outer conduit extends further toward the arc chamber than a distal end of the inner conduit. In some embodiments, a volume between the inner conduit and the outer conduit defines an outer annular channel, and a second gas source is in communication with the outer annular channel. In certain embodiments, the outer conduit and the inner conduit are configured such that gas flow through the inner channel and the outer annular channel is laminar. In certain embodiments, the outer conduit and the inner conduit are configured such that gas flow through the inner channel and the outer annular channel is turbulent. In some embodiments, a heat sink is in thermal communication with the inner conduit. In certain embodiments, the heat sink comprises a structure with fluid channels in communication with a chiller. In certain embodiments, a fluid inlet and fluid outlet are in fluid communication with the chiller and the heat sink, and the inner conduit, the outer conduit, the fluid inlet and the fluid outlet are all contained within a multipurpose conduit. In certain embodiments, the multipurpose conduit has four compartments at a distal end to accommodate two fluid channels and two gas channels, and has two concentric conduits at a distal end. In certain embodiments, the two fluid channels are connected along a length of the multipurpose conduit. In certain embodiments, the heat sink comprises a Peltier cooling element. In some embodiments, the first feed gas is dimethylaluminum chloride.

According to another embodiment, an ion implanter is disclosed. The ion implanter comprises an ion source; a workpiece holder; and one or more beamline components disposed between the ion source and the workpiece holder; wherein a coaxial gas conduit is used to introduce one or more feed gasses to the ion source. In some embodiments, the coaxial gas conduit comprises an inner conduit defining an inner channel to introduce a first feed gas into the ion source and also comprises an outer conduit. In certain embodiments, a volume between the inner conduit and the outer conduit defines an outer annular channel. In certain embodiments, a second gas source is in communication with the outer annular channel to introduce a second feed gas to the ion source. In some embodiments, the ion implanter comprises a chiller having a fluid inlet and a fluid outlet, wherein the fluid inlet, the fluid outlet, the inner channel and the outer annular channel are all contained within a multipurpose conduit that is in fluid communication with the ion source. In some embodiments, the inner conduit is actively cooled using a heat sink or electronic cooler.

### BRIEF DESCRIPTION OF THE FIGURES

For a better understanding of the present disclosure, reference is made to the accompanying drawings, which are incorporated herein by reference and in which:

FIG. 1 is an indirectly heated cathode (IHC) ion source having a coaxial gas conduit in accordance with one embodiment;

FIGS. 2A-2C show the proximal end, an intermediate region and the distal end of a multipurpose conduit, respectively, according to one embodiment; and

FIG. 3 shows an ion implantation system that may use the ion source of FIG. 1.

### DETAILED DESCRIPTION

As noted above, certain gasses, such as dimethylaluminum chloride (DMAC; (CH₃) ₂AlCl), are subject to decomposition at high temperatures. As an example, DMAC decomposes at relatively low temperatures, such as less than 200° C. One of the decomposition materials may be carbon, which may then deposit in the gas conduit or elsewhere within the ion source.

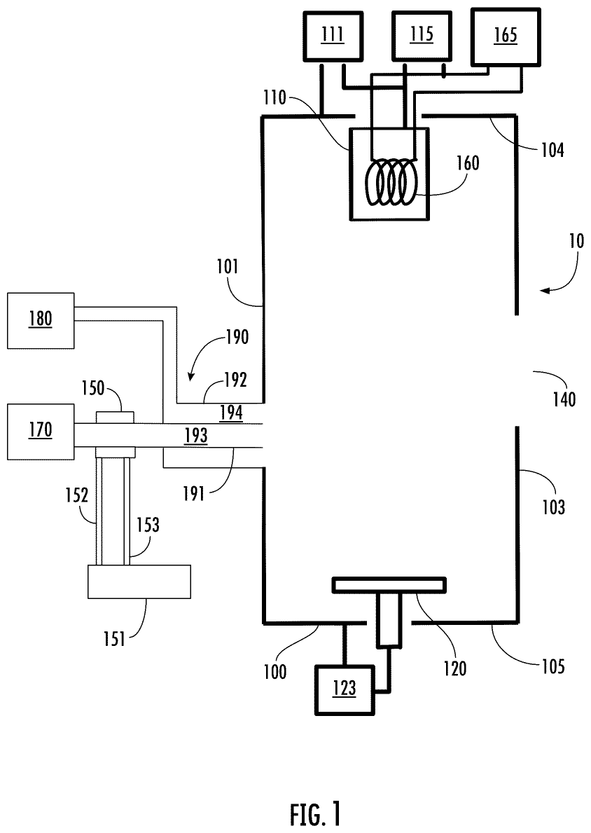

FIG. 1 shows an IHC ion source 10 that overcomes these issues. The IHC ion source 10 includes an arc chamber 100, comprising two opposite ends, and walls 101 connecting to these ends. The walls 101 of the arc chamber 100 may be constructed of an electrically conductive material and may be in electrical communication with one another. In some embodiments, a liner may be disposed proximate one or more of the walls 101. A cathode 110 is disposed in the arc chamber 100 at a first end 104 of the arc chamber 100. A filament 160 is disposed behind the cathode 110. The filament 160 is in communication with a filament power supply 165. The filament power supply 165 is configured to pass a current through the filament 160, such that the filament 160 emits thermionic electrons. Cathode bias power supply 115 biases filament 160 negatively relative to the cathode 110, so these thermionic electrons are accelerated from the filament 160 toward the cathode 110 and heat the cathode 110 when they strike the back surface of cathode 110. The cathode bias power supply 115 may bias the filament 160 so that it has a voltage that is between, for example, 200V to 1500V more negative than the voltage of the cathode 110. The cathode 110 then emits thermionic electrons on its front surface into arc chamber 100.

Thus, the filament power supply 165 supplies a current to the filament 160. The cathode bias power supply 115 biases the filament 160 so that it is more negative than the cathode 110, so that electrons are attracted toward the cathode 110 from the filament 160. In certain embodiments, the cathode 110 may be biased relative to the arc chamber 100, such as by bias power supply 111. In other embodiments, the cathode 110 may be electrically connected to the arc chamber 100, so as to be at the same voltage as the walls 101 of the arc chamber 100. In these embodiments, bias power supply 111 may not be employed and the cathode 110 may be electrically connected to the walls 101 of the arc chamber 100. In certain embodiments, the arc chamber 100 is connected to electrical ground.

On the second end 105, which is opposite the first end 104, a repeller 120 may be disposed. The repeller 120 may be biased relative to the arc chamber 100 by means of a repeller bias power supply 123. In other embodiments, the repeller 120 may be electrically connected to the arc chamber 100, so as to be at the same voltage as the walls 101 of the arc chamber 100. In these embodiments, repeller bias power supply 123 may not be employed and the repeller 120 may be electrically connected to the walls 101 of the arc chamber 100. In still other embodiments, a repeller 120 is not employed.

The cathode 110 and the repeller 120 are each made of an electrically conductive material, such as a metal or graphite.

In certain embodiments, a magnetic field is generated in the arc chamber 100. This magnetic field is intended to confine the electrons along one direction. The magnetic field typically runs parallel to the walls 101 from the first end 104 to the second end 105. For example, electrons may be confined in a column that is parallel to the direction from the cathode 110 to the repeller 120. Thus, electrons do not experience any electromagnetic force to move in this direction. However, movement of the electrons in other directions may experience an electromagnetic force.

Disposed on one side of the arc chamber 100, referred to as the extraction plate 103, may be an extraction aperture 140. In FIG. 1, the extraction aperture 140 is disposed on a side that is perpendicular to the page.

Further, the IHC ion source 10 may be in communication with at least two gas sources. The first gas source 170 may contain a first gas that is susceptible to decomposition. In certain embodiments, the first gas is an organoaluminium compound, which is a compound in which an aluminum atom is bonded with a carbon atom. In certain embodiments, the organoaluminium compound contains a halogen and aluminum. In certain embodiments, this first gas may be dimethylaluminum chloride (DMAC; (CH₃) ₂AlCl). Other gases that include a metal atom bonded to a carbon atom may also be used. In some embodiments, this first gas comprises carbon, a metal and a halogen. In other embodiments, this first gas comprises carbon and one or more other species. The first gas source 170 may also include various diluent gasses, such as hydrogen, argon or other gasses. In other words, the first gas source 170 contains the first gas, but may also include other gasses. The second gas source 180 may contain a second gas, which may be an inert or diluent gas, such as argon, hydrogen, xenon, or others.

A coaxial gas conduit 190 is made up of an inner conduit 191 and an outer conduit 192. The volume within the inner conduit 191 defines an inner channel 193, while the volume between the inner conduit 191 and the outer conduit 192 defines an outer annular channel 194. The first gas source 170 is in communication with the proximal end of the inner channel 193. The second gas source 180 is in communication with the proximal end of the outer annular channel 194. The distal end of each channel is disposed at or proximate to the wall 101 of the arc chamber 100.

The inner diameter of the outer conduit 192 may be between 0.25 and 0.50 inches, while the inner conduit 191 may have an outer diameter that results in a ring having an annular gap of between 0.03 and 0.15 inches between the inner conduit 191 and the outer conduit 192. The inner diameter of the inner conduit 191 may be between 0.03 and 0.25 inches. Further, since the conduits are subject to very low pressure differentials, the thickness of the conduits may be as thin as 0.005 inches, while thicknesses up to about 0.1 inches may be used. Note that these are exemplary dimensions and other dimensions are also possible.

Note that the inner conduit 191 does not contact the walls 101 of the arc chamber 100. Rather, only the outer conduit 192 is affixed to the walls 101 of the arc chamber 100. The gap between the outer wall of the outer conduit 192 and the inner conduit 191 serves to reduce the heat experienced by the inner conduit 191.

In certain embodiments, the distal end of the inner conduit 191 extends as far toward the arc chamber 100 as the distal end of the outer conduit 192. In other embodiments, the distal end of the inner conduit 191 may be recessed, as compared to the distal end of the outer conduit 192.

Further, in some embodiments, the inner conduit 191 is in thermal communication with a heat sink 150 to further reduce its temperature. The heat sink 150 may be implemented in various ways. For example, in one embodiment, the heat sink 150 may comprise a thermally conductive structure, such as a metal structure, with channels through which a cooling fluid may pass. The cooling fluid may be circulated in a closed loop, passing through the heat sink 150, fluid outlet 152, chiller 151 and fluid inlet 153.

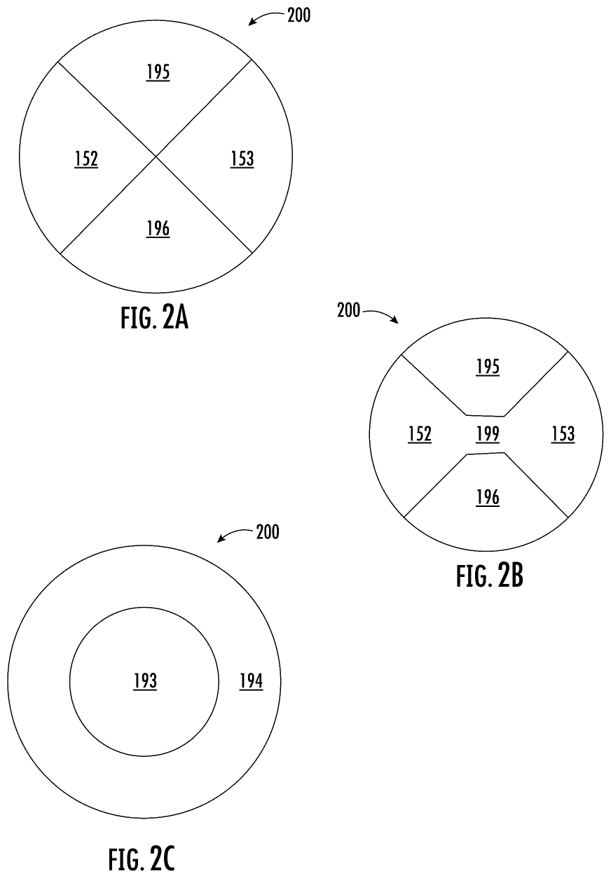

In some embodiments, the heat sink 150, the inner conduit 191 and the outer conduit 192 may be combined into a single component, referred to as a multipurpose conduit. This multipurpose conduit may be formed using additive manufacturing and may be made of a refractory metal, such as tungsten or molybdenum. FIGS. 2A-2C show one embodiment of this multipurpose conduit 200. A cross section of the proximal end of the multipurpose conduit 200 according to one embodiment is shown in FIG. 2A. A cross section of the distal end according to this embodiment is shown in FIG. 2C. The multipurpose conduit 200 may have a cylindrical shape and may be formed with four separate compartments at its proximal end, corresponding to the fluid inlet 153, the fluid outlet 152, a first gas channel 195 and a second gas channel 196. The first gas channel 195 is in fluid communication with the first gas source 170, while the second gas channel 196 is in fluid communication with the second gas source 180. The four compartments may travel parallel to one another for a portion of the length of the multipurpose conduit 200. Note that in this embodiment, the fluid inlet 153, which contains the coldest fluid, travels adjacent to the first gas channel 195 and the second gas channel 196. The fluid inlet 153 and fluid outlet 152 may connect at a point along the length of the multipurpose conduit 200. For example, at an intermediate location, as shown in FIG. 2B, a cross cut 199 may be added to allow fluid communication between the fluid inlet 153 and fluid outlet 152. Additionally, the shape of the first gas channel 195 and the second gas channel 196 may change to create the cross-section visible at the distal end, as shown in FIG. 2C. In other words, the first gas channel 195 becomes the inner channel 193, while the second gas channel 196 becomes the outer annular channel 194. This cross-section of the distal end is visible from within the arc chamber 100. In certain embodiments, the inner conduit 191 is not in physical contact with the outer conduit 192 for at least 1 inch before the distal end of the outer conduit 192. This distance decreases the thermal conductivity of the path from the outer conduit 192 to the inner conduit 191.

Note that the selection of the function of each compartment is implementation dependent. For example, in another embodiment, the fluid inlet 153 and fluid outlet 152 may be located adjacent to one another. Further, the size of each compartment does not need to be equal. In other words, the multipurpose conduit 200 may be designed in any manner that includes four compartments at the proximal end to accommodate two gas channels and two fluid channels, and also includes two concentric conduits at the distal end to accommodate the gas channels. Further, the multipurpose conduit 200 also includes a connection between two of the compartments within the length of the conduit to allow flow of the fluid from the proximal end, through a portion of the conduit and then back to the proximal end. Further, in certain embodiments, there is no physical contact between the two concentric channels within 1 inch of the distal end to minimize heat transfer from the outer conduit 192 to the inner conduit 191. Thus, the presence of the fluid inlet 153 adjacent to the first gas channel 195 serves as the heat sink.

Further, while FIG. 2A shows the four compartments as wedges of a circle, the four compartments may be shaped and arranged differently.

Further, in another embodiment, the multipurpose conduit may only include the first gas channel 195, the fluid inlet 153 and the fluid outlet 152 (as shown in FIG. 1). The second gas channel 196 is then merged with the first gas channel 195 downstream from the heat sink 150 (i.e. closer to the arc chamber 100).

While the above disclosure describes the heat sink as a structure having fluid channels, other embodiments may be used. For example, electronic cooling elements, such as Peltier cooling elements, may be used to reduce the temperature of the inner conduit 191, if desired. Thus, to reduce the risk of decomposition of the feed gas, the inner conduit 191 may be actively cooled.

In operation, a first gas, which may be DMAC or another gas that may decompose at high temperatures, flows from the first gas source 170 and through the inner channel 193 to reach the arc chamber 100. At the same time, a second gas, which may be an inert gas, such as argon or xenon, flows from the second gas source 180 and through the outer annular channel 194 to reach the arc chamber 100. The outer conduit 192 contacts the walls 101 of the arc chamber 100, which tends to heat the second gas. However, the second gas is less sensitive to high temperatures, and is therefore unaffected by the rise in temperature. The outer annular channel 194 serves to physically isolate the inner conduit 191 from the walls 101 of the arc chamber 100. Therefore, the inner conduit 191 is at a lower temperature than the outer conduit 192. Further, the heat sink 150 also serves to control the temperature of the inner conduit 191. As the gasses first enter the arc chamber 100, the second gas serves to shield the first gas from the plasma. This delays the decomposition of the first gas, which now occurs away from the inner conduit 191. In this case, the inner conduit 191 and outer conduit 192 may be designed to achieve laminar flow.

In other embodiments, it may be advantageous to mix the gasses prior to introduction into the arc chamber 100. In that case, the distal end of the inner conduit 191 may terminate before the distal end of the outer conduit 192. Furthermore, the inner conduit 191 and outer conduit 192 may be designed to achieve turbulent flow.

In yet other embodiments, there may not be a second gas source 180. Rather, the outer annular channel 194 is only used as a thermal isolator between the walls 101 of the arc chamber 100 and the inner conduit 191.

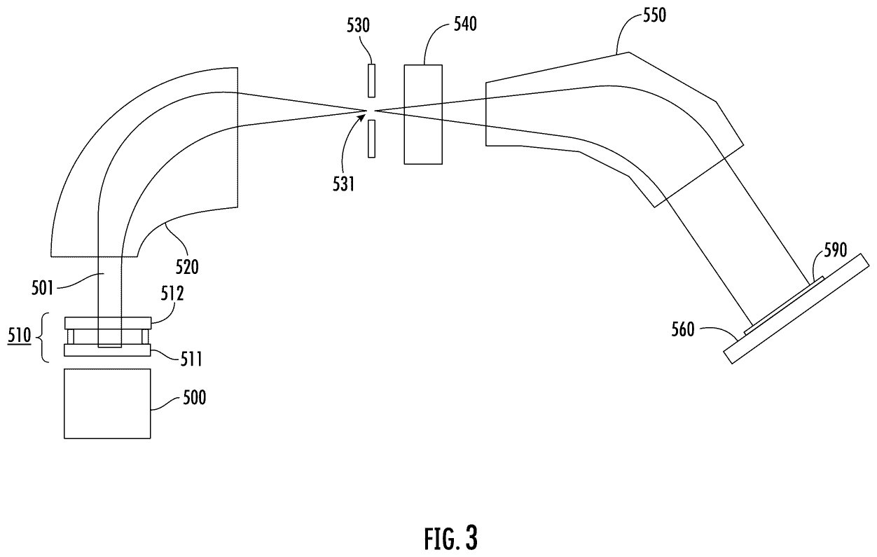

FIG. 3 shows an ion implanter that may utilize the ion source described herein. The ion implanter includes an ion source 500, which may be the ion source described above. As noted above, in certain embodiments, the ion source 500 may be an IHC ion source. In another embodiment, the ion source 500 may be an RF ion source. In this embodiment, an RF antenna may be disposed against a dielectric window. This dielectric window may comprise part or all of one of the chamber walls. The RF antenna may comprise an electrically conductive material, such as copper. An RF power supply is in electrical communication with the RF antenna. The RF power supply may supply an RF voltage to the RF antenna. The power supplied by the RF power supply may be between 0.1 and 10 kW and may be any suitable frequency, such as between 1 and 100 MHz. Further, the power supplied by the RF power supply may be pulsed. Other embodiments are also possible. For example, the plasma may be generated in a different manner, such as by a Bernas ion source, a capacitively coupled plasma (CCP) source, microwave or ECR (electron-cyclotron-resonance) ion source. The manner in which the plasma is generated is not limited by this disclosure. In all of these embodiments, a coaxial gas conduit, such that that described above, is used to introduce gas to the ion source 500.

One chamber wall, referred to as the extraction plate, includes an extraction aperture. The extraction aperture may be an opening through which the ions 501 generated in the ion source chamber are extracted and directed toward a workpiece 590. The extraction aperture may be any suitable shape. In certain embodiments, the extraction aperture may be oval or rectangular shaped.

Disposed outside and proximate the extraction aperture of the ion source 500 are extraction optics 510. In certain embodiments, the extraction optics 510 comprise one or more electrodes. In certain embodiments, the extraction optics 510 comprises a suppression electrode 511, which is negatively biased relative to the plasma so as to attract ions through the extraction aperture. The suppression electrode 511 may be electrically biased using a suppression power supply. The suppression electrode 511 may be biased so as to be more negative than the extraction plate of the ion source 500.

In some embodiments, the extraction optics 510 includes a second electrode 512. The second electrode 512 may be disposed proximate the suppression electrode 511. The second electrode 512 may be electrically connected to a second electrode power supply. In other embodiments, the second electrode 512 may be electrically grounded so that the second electrode power supply is not used.

In other embodiments, the extraction optics 510 may comprise in excess of two electrodes, such as three electrodes or four electrodes. In these embodiments, the electrodes may be functionally and structurally similar to those described above, but may be biased at different voltages.

Located downstream from the extraction optics 510 is a mass analyzer 520. The mass analyzer 520 uses magnetic fields to guide the path of the extracted ions 501. The magnetic fields affect the flight path of ions according to their mass and charge. A mass resolving device 530 that has a resolving aperture 531 is disposed at the output, or distal end, of the mass analyzer 520. By proper selection of the magnetic fields, only those ions 501 that have a selected mass and charge will be directed through the resolving aperture 531. Other ions will strike the mass resolving device 530 or a wall of the mass analyzer 520 and will not travel any further in the system.

One or more beamline components may be disposed downstream from the mass resolving device 530. For example, a collimator 540 may be disposed downstream from the mass resolving device 530. The collimator 540 accepts the extracted ions 501 that pass through the resolving aperture 531 and creates a ribbon ion beam formed of a plurality of parallel or nearly parallel beamlets. In other embodiments, the ion beam may be a spot beam. In this embodiment, an electrostatic scanner is used to move the spot beam in the first direction, as defined below.

Located downstream from the collimator 540 may be an acceleration/deceleration stage 550. The acceleration/deceleration stage 550 may be an electrostatic filter. The electrostatic filter is a beam-line lens component configured to independently control deflection, deceleration, and focus of the ion beam. Located downstream from the acceleration/deceleration stage 550 is the workpiece holder 560.

The workpiece 590, which may be, for example, a silicon wafer, a silicon carbide wafer, or a gallium nitride wafer, is disposed on the workpiece holder 560.

The embodiments described above in the present application may have many advantages. Certain gasses, such as DMAC, are known to decompose at elevated temperatures. In some ion sources, this decomposition may begin to occur within the gas conduit, which causes the gas conduit to become clogged. By utilizing a coaxial gas conduit, the inner conduit, which carries the DMAC, may remain at a cooler temperature than would otherwise occur. This allows the gas to remain in gaseous form longer and reduces the amount of deposition in the gas conduit. This results in extended life before maintenance for the ion source.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An indirectly heated cathode ion source, comprising:
an arc chamber, comprising a plurality of walls;
an indirectly heated cathode disposed in the arc chamber;
a coaxial gas conduit to introduce one or more feed gasses to the arc chamber, wherein the coaxial gas conduit comprises:
an inner conduit defining an inner channel to introduce a first feed gas into the arc chamber; and
an outer conduit.

2. The indirectly heated cathode ion source of claim 1, wherein the outer conduit is affixed to one wall of the plurality of walls of the arc chamber and the inner conduit is thermally isolated from the outer conduit at its distal end.

3. The indirectly heated cathode ion source of claim 1, wherein a distal end of the inner conduit extends toward the arc chamber as far as a distal end of the outer conduit.

4. The indirectly heated cathode ion source of claim 1, wherein a distal end of the outer conduit extends further toward the arc chamber than a distal end of the inner conduit.

5. The indirectly heated cathode ion source of claim 1, wherein a volume between the inner conduit and the outer conduit defines an outer annular channel, and wherein a second gas source is in communication with the outer annular channel.

6. The indirectly heated cathode ion source of claim 5, wherein the outer conduit and the inner conduit are configured such that gas flow through the inner channel and the outer annular channel is laminar.

7. The indirectly heated cathode ion source of claim 5, wherein the outer conduit and the inner conduit are configured such that gas flow through the inner channel and the outer annular channel is turbulent.

8. The indirectly heated cathode ion source of claim 1, further comprising a heat sink in thermal communication with the inner conduit.

9. The indirectly heated cathode ion source of claim 8, wherein the heat sink comprises a structure with fluid channels in communication with a chiller.

10. The indirectly heated cathode ion source of claim 9, further comprising a fluid inlet and fluid outlet in fluid communication with the chiller and the heat sink, and wherein the inner conduit, the outer conduit, the fluid inlet and the fluid outlet are all contained within a multipurpose conduit.

11. The indirectly heated cathode ion source of claim 10, wherein the multipurpose conduit has four compartments at a proximal end to accommodate two fluid channels and two gas channels, and has two concentric conduits at a distal end.

12. The indirectly heated cathode ion source of claim 11, wherein the two fluid channels are connected along a length of the multipurpose conduit.

13. The indirectly heated cathode ion source of claim 8, wherein the heat sink comprises a Peltier cooling element.

14. The indirectly heated cathode ion source of claim 1, wherein the first feed gas is dimethylaluminum chloride.

15. An ion implanter, comprising:
an ion source;
a workpiece holder; and
one or more beamline components disposed between the ion source and the workpiece holder;
wherein a coaxial gas conduit is used to introduce one or more feed gasses to the ion source.

16. The ion implanter of claim 15, wherein the coaxial gas conduit comprises an inner conduit defining an inner channel to introduce a first feed gas into the ion source and also comprises an outer conduit.

17. The ion implanter of claim 16, wherein a volume between the inner conduit and the outer conduit defines an outer annular channel.

18. The ion implanter of claim 17, wherein a second gas source is in communication with the outer annular channel to introduce a second feed gas to the ion source.

19. The ion implanter of claim 17, further comprising a chiller having a fluid inlet and a fluid outlet, wherein the fluid inlet, the fluid outlet, the inner channel and the outer annular channel are all contained within a multipurpose conduit that is in fluid communication with the ion source.

20. The ion implanter of claim 16, wherein the inner conduit is actively cooled using a heat sink or electronic cooler.
